(19) United States
(12) Patent Application Publication
(10) Pub. No.: US 2018/0286998 A1
(43) Pub. Date: Oct. 4, 2018

(54) Mechanical Matrix for Enhancing the Thermomechanical and Chemical Reliability of Optoelectronic Device Technologies

(71) Applicant: The Board of Trustees of the Leland Stanford Junio University, Palo Alto, CA (US)

(72) Inventors: Brian Lyndon Watson, Cape Town (ZA); Nicholas Rolston, Stanford, CA (US); Adam Printz, San Mateo, CA (US); Reinhold H. Dauskardt, Menlo Park, CA (US)

(21) Appl. No.: 15/943,085

(22) Filed: Apr. 2, 2018

Related U.S. Application Data
(60) Provisional application No. 62/479,773, filed on Mar. 31, 2017.

(51) Int. Cl. H01L 31/048; H01L 31/0224; H01L 31/02; H01L 31/0216

(52) U.S. Cl. CPC H01L 31/0481; H01L 31/02168; H01L 31/02008; H01L 31/022425

(57) ABSTRACT

Mechanical scaffolds within optoelectronic devices are provided to enhance the overall thermomechanical and chemical stability of these devices. For example, extremely fragile perovskite solar cells were reinforced by scaffolding in the following way: following printing, the scaffold was sequentially filled with an electron (hole) transport layer, photoactive perovskite semiconductor, a hole (electron) transport layer, and finally capped with a top electrode. The scaffold provided structural reinforcement to the fragile perovskite layer and inhibited crack formation in the layer that would lead to device failure.

### CROSS REFERENCE TO RELATED APPLICATIONS

This application claims the benefit of U.S. provisional patent application No. 62/479,773, filed on Mar. 31, 2017, and hereby incorporated by reference in its entirety.

### FIELD OF THE INVENTION

This invention relates to optoelectronic devices.

### BACKGROUND

Solar cells are most commonly evaluated according to their efficiency in converting sunlight into electrical power. However, in order for a solar cell design to be practically viable, it must meet additional requirements having to do with lifetime, resistance to damage or failure in operation etc. These other requirements pose especially challenging difficulties when the use of mechanically fragile materials as active media for solar cells is considered. Accordingly, it would be an advance in the art to provide mechanically robust solar cells having mechanically fragile active media.

### SUMMARY

This work describes the use of scaffolds within the active conducting and semiconducting materials, be it, some, or all of these materials that constitute an optoelectronic (perovskite) device to enhance the overall thermomechanical and chemical stability of these devices.

For example, extremely fragile perovskite solar cells were reinforced by scaffolding in the following way: following printing, the scaffold was sequentially filled with an electron (hole) transport layer, photoactive perovskite semiconductor, a hole (electron) transport layer, and finally capped with a top electrode. The scaffold provided structural reinforcement to the fragile perovskite layer and inhibited crack formation in the layer that would lead to device failure.

### BRIEF DESCRIPTION OF THE DRAWINGS

FIGS. 1A-B show an embodiment of the invention.

FIG. 1C shows a detail view of a single cell of a composite solar cell.

FIG. 1D shows geometrical parameters relating to exemplary composite solar cells.

FIG. 1E shows an aperiodic arrangement of cells in a matrix layer.

FIGS. 2A-C show an exemplary fabrication sequence for a composite solar cell.

FIGS. 3A-D show characterization results for fabrication of a composite solar cell.

FIGS. 4A-B show mechanical strength results for conventional and composite solar cells.

FIGS. 5A-D show optical performance results for composite solar cells.

FIGS. 6A-D show hysteresis results for planar and composite solar cells.

FIG. 6E shows measured efficiency values for planar and composite solar cells vs. time.

### DETAILED DESCRIPTION

Section A is a description of general principles relating to embodiments of the invention. Section B is a description of experiments relating to exemplary embodiments of the invention.

### A) General Principles

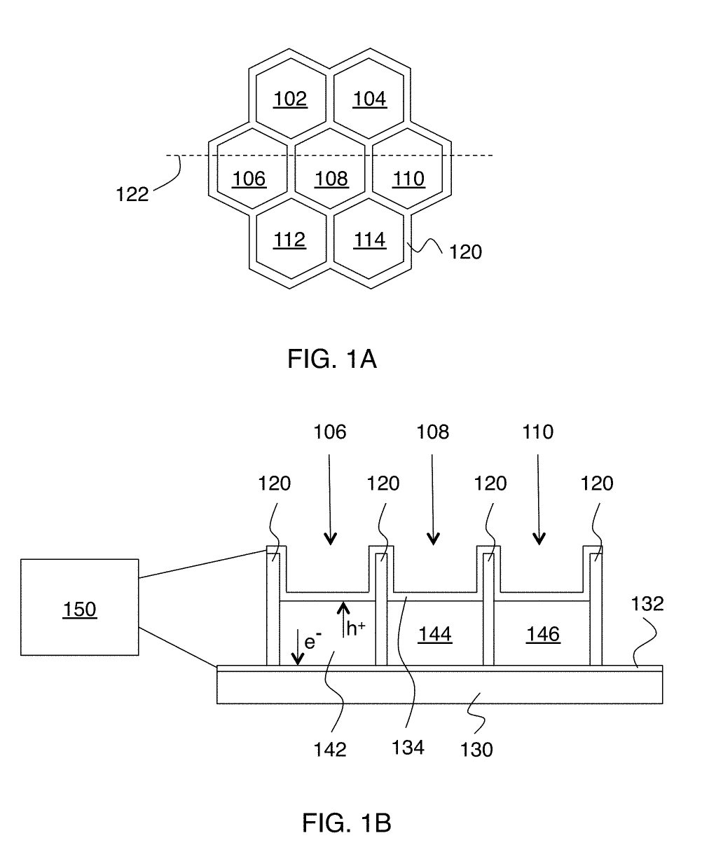

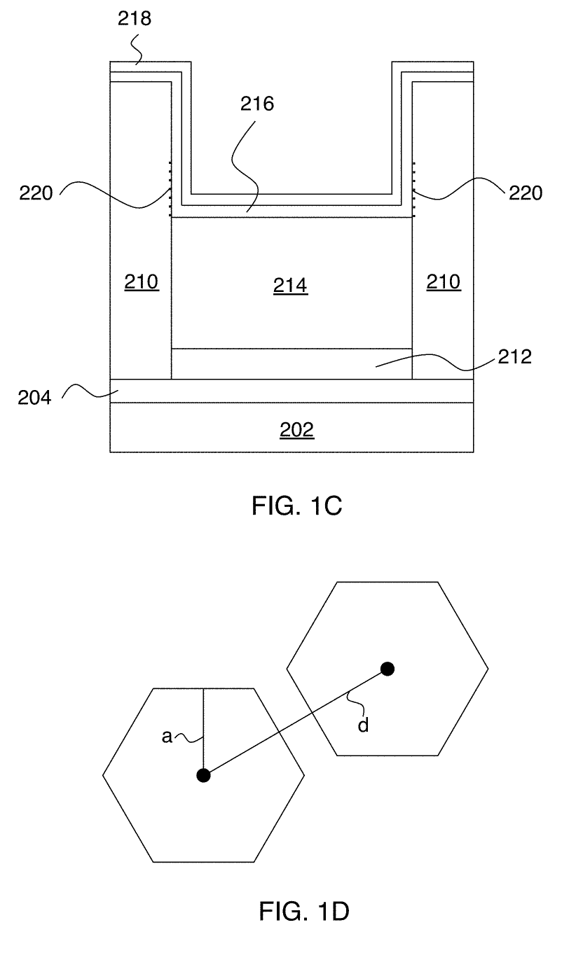

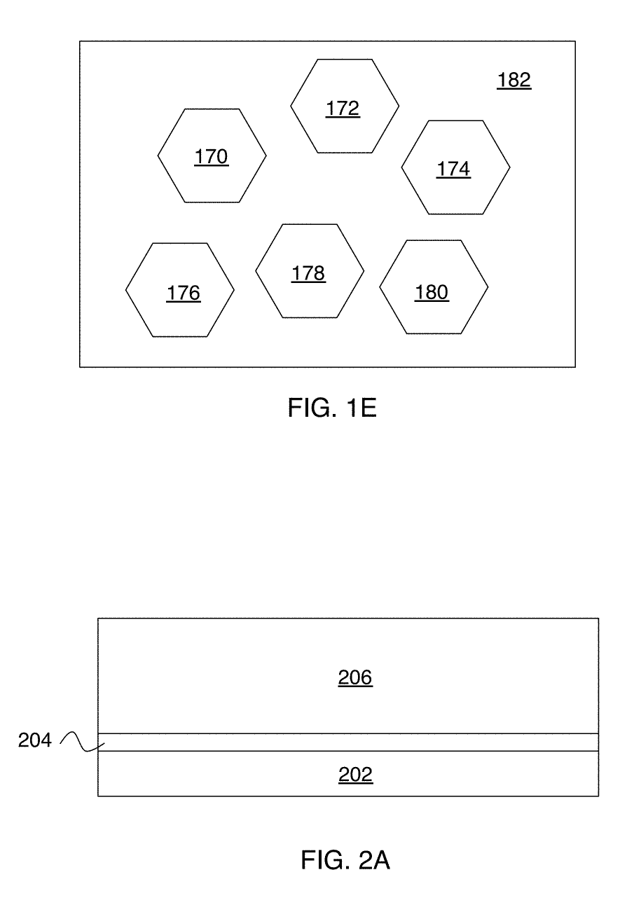

FIGS. 1A-B show an exemplary embodiment of the invention. FIG. 1A is a top view and FIG. 1B is a cross section view along line 122 of FIG. 1A. Here an electrically insulating matrix layer 120 has laterally separated cells e.g., 102, 104, 106, 108, 110, 112, 114 on FIG. 1A. Any number of such cells can be employed. The structure also includes two or more optoelectronic device elements, e.g., 142, 144, 146 on FIG. 1B. Each of the optoelectronic device elements occupies a corresponding one of the laterally separated cells of the electrically insulating matrix layer, as shown on FIG. 1B. Matrix layer 120 need not be composed entirely of an insulating material. It suffices for it to provide electrical insulation of the cells from each other, so matrix layer 120 can be a conducting or semiconducting core with insulating surfaces. For ease of description, such a matrix layer is also often referred to as a scaffold in the following description. The two terms are taken to be synonyms in this work.

FIG. 1B shows a preferred device configuration where the entire arrangement is disposed on a substrate 130, and where a first electrode 132 and a second electrode 134 make contact to the optoelectronic device elements such that all of the optoelectronic device elements are electrically connected to each other in parallel. As a result, the structure acts as a single composite solar cell in providing electrical power to a load 150. For simplicity, electron and hole transport layers that may be present in real devices are omitted from the schematics of FIGS. 1A-B. Any other scheme of electrically connecting the optoelectronic device elements to each other can also be employed.

In preferred embodiments, the optoelectronic device elements include a perovskite material as an active medium that provides electrical charge carriers in response to incident illumination (e.g., as schematically shown in 142 of FIG. 1B). Here, a perovskite is defined as a material with a chemical formula ABX₃ where A is a monovalent cation, B is a divalent metal cation, and X is a monovalent (typically halide) anion. All three components (i.e., A, B, or X) can comprise either a homogeneous or heterogeneous mixture of elements and molecules (e.g., A can be some composition of methylammonium (CH₃NH₃⁺), formamidinium (CH₃(NH₂)₂⁺), Cs⁺, etc., B some composition Pb²⁺, Sn²⁺, Ge²⁺, and/or other divalent metal cations, and X is typically some composition of Cl—, Br—, I—, BF₄—, PF₆—, SCN—, etc.). One example of a perovskite molecular formula would be CH₃NH₃PbI₃ while another would be Cs_{0.05}[(CH₃NH₃)_{0.17}(CH₃(NH₂)₂)_{0.83}]_{0.95}Pb(I_{0.83}Br_{0.17})₃.

As indicated below, it is preferred for the optoelectronic device elements to be physically distinct from each other. A preferred method of accomplishing this is to ensure that the optoelectronic device elements partially fill the laterally separated cells in a vertical direction perpendicular to a lateral plane of the matrix layer, as opposed to completely filling the cells, also as shown on FIG. 1B. In other embodiments, the optoelectronic device elements completely fill the cells vertically.

The matrix layer is preferably impermeable to diffusion of chemical species of the optoelectronic device elements. The laterally separated cells can be configured as a periodic array of cells or as an aperiodic arrangement of cells. In cases where a periodic array of cells is used, it is preferred for the cells to be regular hexagons. Of course the cells can have any shape, and different cells in the same matrix layer can have the same shape or different shapes. FIG. 1E shows a matrix layer 182 having an aperiodic arrangement of cells 170, 172, 174, 176, 178, 180.

The chemistry of the matrix layer can be readily tuned by materials selection. Since the matrix layer can be fabricated in a number of ways, including lithographically patterning, embossing, printing (e.g., inkjet, 3D, doctor-blading, screen printing, slot-die), evaporation, and solution-based deposition, the material library from which to select is nearly limitless. Additionally, each individual cell is isolated, therefore, if the matrix layer comprises an impermeable material, it will prevent the lateral diffusion of species into or out of each cell. Also, failure of any individual cell is limited to that cell and will not cause failure of the entire device.

The substrate 130 can be flexible or rigid.

Numerous applications are possible. The matrix layer can be integrated into any film that requires enhancement of its thermomechanical or chemical resilience. The primary demonstrated application for the matrix layer is reinforcing the perovskite and charge transport layers of perovskite solar cells which, by themselves in planar devices have extremely low thermomechanical and chemical stability, completely limiting their technological viability. The optoelectronic device structure can be configured as various devices, including but not limited to: solar cells, photovoltaic devices, light emitting diodes, and photodetectors.

There are several key advantages to integrating such matrix layers into thin films.

1) Mechanical Stability: In our demonstrated example, the perovskite active layer in solar cells are extremely fragile and have cohesive fracture energies <1.5 J m². For example, CH₃NH₃PbI₃ has a cohesive fracture energy of 0.37 J m². However, when infused into a cross-linked polymer scaffold, the cohesive fracture energy of the layer increased to >10 J m⁻², which is competitive with established solar technologies such as crystalline silicon (c—Si), cadmium telluride (CdTe), and copper indium gallium diselenide (CIGS) devices. The fracture toughness of the typically fragile active layers are greatly enhanced by infusion into scaffolding.
2) Chemical Stability: Each individual cell is laterally isolated, therefore, if the material infused into the cells of the scaffold is chemically unstable, selection of a scaffold material that inhibits diffusion will improve the chemical resilience of the device. Complete isolation of each individual cell can be imparted by further encapsulation on the top and bottom of the cells, which would prevent out-of-plane diffusion in addition to the already inhibited lateral diffusion. In the case of a pinhole in the device encapsulants, isolation of the individual cells by the scaffold inhibits destructive lateral diffusion of chemical species from cell to cell, preventing device failure.

Possible modifications and variations include:

1) Scaffold Geometry: The geometry may be changed to tune the mechanical properties of the scaffold or the optoelectronic properties of the materials contained within the scaffold. The dimensions of the scaffold walls (i.e., wall width, wall height), shape of the open cells (e.g., hexagons, circles, squares), and periodicity (although periodicity is not required) between the scaffold pores are some parameters that can be adjusted readily.
2) Scaffold Materials: The scaffolds have been demonstrated with cresol novolac epoxy resins, but materials including, but not limited to epoxies, ceramics, polymers, metals, and materials comprising two or more classes of materials (i.e., composites) can be utilized as applications demand.
3) Scaffold Functionality: The scaffold itself may also be electronically active, optically active or optoelectronically active. By this, we mean that the materials of the scaffold, while acting to chemically and mechanically shield and isolate weaker and less stable materials of the device, may also act as active conducting, or semiconducting materials in the device, responsible for carrier generation or transport. The scaffold material may also be optically active, in that it functions to direct light impinging on it, from outside of the device or from within the device, in a desired direction.
4) Substrate Material: The demonstration of reinforcing scaffolds patterned on rigid substrates (i.e., glass and silicon) is not the only possible type of substrates that scaffolds can be patterned on. The scaffolds can be printed onto any arbitrary substrate. Flexible substrates such as PET or PEN and stretchable substrates such as PDMS and polyurethane are just a few examples.
5) Fabrication Technique: While the initial demonstration of the technique used photolithography to pattern the scaffolds, many other techniques such as embossing, nano-imprint lithography (NIL), inkjet, 3D, or screen printing can be used to fabricate the scaffolds.

From an alternative point of view, this approach is useful for optoelectronic devices comprising two compositions. The first composition will encompass one or more active materials at least capable of emitting or absorbing light (composition 1), which is disposed into a mechanically robust thin-film scaffold (<100 μm thick) with an array of isolated, periodic or aperiodic open cells (or pores) patterned onto a substrate (composition 2). Composition 1 will be a brittle material, typically with cohesive fracture energies below 5 J m-², while composition 2 will be a tougher material with cohesive fracture energies greater than that of composition 1. The mechanical and/or chemical stability imparted upon composition 1 by composition 2 requires that it will be fully disposed into composition 2 with no contiguous planar layer of composition 1 sitting on top of composition 2.

B) Experimental examples

### B1) Introduction

The remarkable potential of organometal trihalide perovskite photoactive materials has recently been demonstrated in the production of efficient solar cells and light-emitting diodes. Their optoelectronic properties are relatively insensitive to crystallographic defects and impurities, enabling highly-efficient solar cells to be fabricated using scalable solution-state processes well suited to low-cost manufacturing. The use of perovskites in photovoltaic devices has been a particularly fruitful avenue, with rapid progress, resulting in an increase of device efficiency from 3.8 to over 22%—comparable to silicon (Si), cadmium telluride (CdTe), and copper indium gallium diselenide (CIGS) devices—in a little over seven years. These high efficiencies, in concert with their solution-processability, promise to reduce the levelized cost of electricity and allow facile integration into flexible technologies.

Realizing the promise of perovskite solar cells, however, requires overcoming several challenges that include their chemical and thermal stability, sensitivity to moisture, light-induced phase segregation (Hoke effect) and extreme mechanical fragility, which stand as obstacles to achieving the required stability and service lifetimes. The field has recently starting shifting focus away from pursuing ever-higher efficiencies toward addressing the challenges that are currently preventing perovskite solar cells from commercialization. Recent publications have begun to address the Hoke effect, as well as thermal and environmental degradation, through material selection and device encapsulation. However, the extreme mechanical fragility of perovskites remains a major obstacle to further technological advance.

In a recent study investigating the fracture properties of a wide variety of solution processed perovskite solar cells, we consistently observed G_{c} values of cohesive and adhesive fracture—a key metric of thermomechanical reliability—well below ˜1.5 J m⁻², values so low they stand to compromise the thermomechanical reliability and operational lifetimes of perovskite solar cells. Based on years of research in microelectronic devices and packaging materials in our own laboratory, we have observed that devices with a G_{c} below 5 J m⁻² are prone to mechanical failure in production due to the stresses from manufacturing and handling.

The field has recently begun to appreciate the mechanical fragility of perovskites; however, the real challenges associated with this fragility have yet to be observed since the focus has been on producing small, lab-scale devices. At the lab scale, the displacements imposed at the edge of devices due to thermal mismatch—which scales with size—are minimal. At the module scale, much larger displacements, and thus shear strains, are generated than for lab-scale devices, leading to residual stresses that drive delamination and result in device failure.

In mature solar technologies such as c—Si and CIGS, it is well established that mechanical properties are excellent predictors for device resilience to environmental stressors that accelerate the evolution of internal defects causing delamination of layered structures. Recent work has demonstrated this concept in metallized surfaces and anti-reflection coatings within solar modules, along with encapsulation and backsheet structures exposed to heat and humidity. Currently, the development of perovskite solar cells has proceeded along a pathway similar to that of organic photovoltaics, except perovskites are even more susceptible to fracture. Clearly, new concepts in the design of solar cells employing such fragile materials are required.

### B2) Technical Approach

Instead of attempting to improve upon the intrinsically fragile nature of perovskites—which is related to their brittle, salt-like crystal structure—a new cell design that extrinsically shields the cells from mechanical stresses is provided.

Inspired by the compound eyes of insects comprising a close-packed array of independent photoreceptor units, we developed the compound solar cell (CSC), a conventional solar cell partitioned by a scaffold into a vast array of smaller, encapsulated, mechanically shielded, and chemically contained perovskite microcells. In this demonstration of the scaffold-partitioned CSC, we utilized a close-packed hexagonal or honeycomb structure design for the scaffold (FIG. 1A). The honeycomb is mechanically resilient to mechanical stresses, and close-packed hexagons exhibit the best combination of mechanical properties, packing efficiency, and reduced internal cell perimeter in comparison to other geometries.

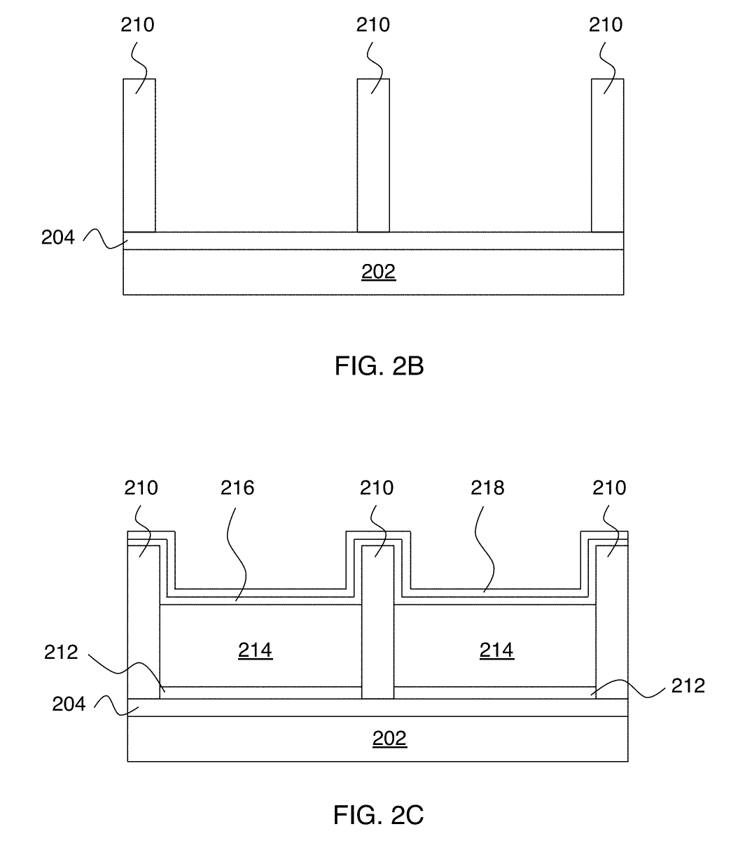

FIG. 1C is an expanded illustration of a single perovskite microcell. Here 202 is an ITO-glass electrode, 204 is the electron transport layer, 210 is the scaffold, 212 is a C₆₀ layer, 214 is the active perovskite layer, 216 is the hole transport layer, and 218 is the back electrode. These elements are described below in greater detail in connection with FIG. 2. The dashed black lines 220 highlight the region where the hole transport layer 216 bonds to the scaffold 210. FIG. 1D shows parameters used to calculate the active photovoltaic surface area of the microcell array, the microcell area fraction (f_{MA}).

Minimizing the internal microcell perimeter decreases the total surface area with which the perovskite contacts the scaffold, and thus, limits the number of charge recombination sites that may be introduced through scaffold partitioning. These geometric arguments suggest that, for CSCs, the honeycomb structure is the optimal structure for providing structural support while sustaining high power conversion efficiencies (PCEs). Given twice the scaffold apothem a (i.e., the wall-to-wall distance, 300 μm, 400 μm, or 450 μm), and the periodicity of the cells, d (i.e., 500 μm), the microcell area fraction (f_{MA}) can be calculated as f_{MA}=(2a)²/d² (FIG. 1D). The f_{MA} of CSCs with scaffold wall widths of 50, 100, and 200 μm were calculated to be 0.81, 0.64, and 0.36, respectively. We demonstrate efficient perovskite CSCs with fracture energies comparable to c—Si, CIGS, and CdTe solar devices, a first for any low-cost solution-processed solar technology and an advance that repositions the viability of perovskite solar cell technology.

### B3) Fabrication Example

FIGS. 2A-C schematically show an exemplary fabrication process for a compound solar cell. FIG. 2A shows a starting structure with an Indium Tin Oxide (ITO)-glass electrode 202, an electron transport layer 204, and photoresist 206 stacked. Here electron transport layer 204 is preferably a mechanically robust, solution processed TiO₂ nanoparticle (NP) electron-transport layer (ETL). Layers 202 and 204 will eventually be the front electrode of the solar cell structure. FIG. 2B shows the result of lithographically patterning polymeric scaffold 210 onto the structure of FIG. 2A. The perovskite microcells are then formed within the spaces defined by the scaffold by evaporation of C₆₀ 212 and spin-coating of the CH₃NH₃PbI₃ perovskite precursor solution to provide perovskite layer 214. The entire structure is then coated with a hole-transport layer 216, preferably PTAA-X (cross-linked PTAA) followed by the reflective back Ag electrode 218. FIG. 2C shows the resulting structure. Further details relating to this example follow.

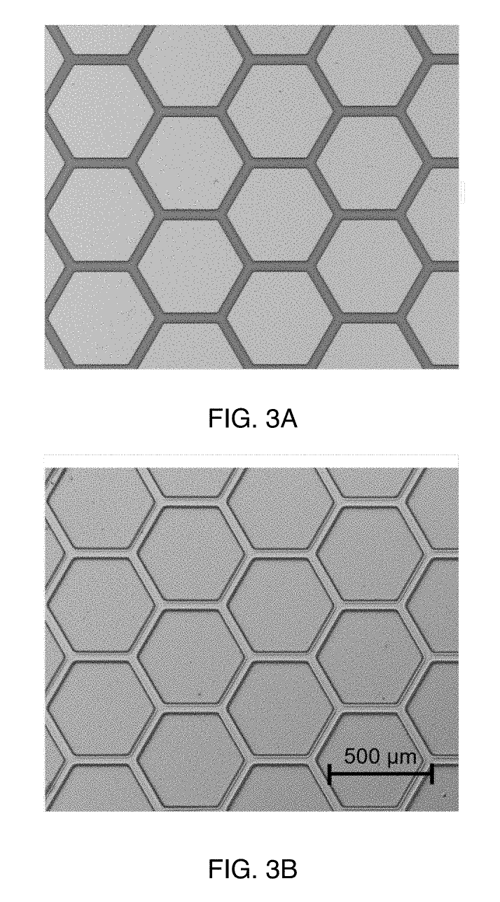

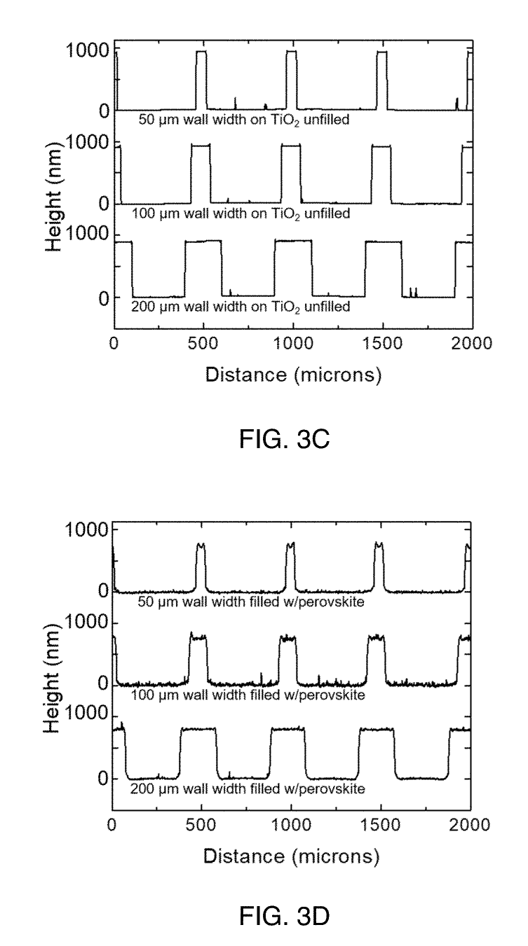

The scaffold was fabricated by photolithographic patterning of a positive photoresist 206 on a transparent, conductive ITO-glass electrode 202 coated with a mechanically robust, solution processed TiO₂ nanoparticle (NP) electron-transport layer (ETL) 204. The hexagonal scaffolds had a center-to-center periodicity of 500 μm and scaffold walls widths of 50, 100, or 200 μm (the microcell sizes were either 450, 400, or 300 μm per 500 μm period). Prior to filling, the scaffolds (FIG. 3A) were hard-baked at 200° C. to increase the degree of cross-linking and prevent dissolution in N,N-dimethylformamide, the solvent of the perovskite precursor solution.

FIG. 3A is an optical micrograph of the unfilled scaffold with 50 μm wall width on a Silicon/TiO₂ substrate. FIG. 3B shows the same scaffold after deposition of C₆₀ and CH₃NH₃PbI₃ perovskite. FIG. 3C-D show profilometry line scans of the scaffolds with 50 μm, 100 μm, and 200 μm wall widths (FIG. 3C) before and (FIG. 3D) after deposition of the perovskite layer, which results in the formation of microcells that intimately contact the scaffold walls.

Thermally evaporated C₆₀ and spin-coated perovskite (CH₃NH₃PbI₃) were sequentially deposited into the scaffold (FIG. 3B). Spin-coated atop these layers and the scaffold was the polymeric hole-transporting material (HTM), cross-linked poly(triarylamine) (PTAA-X), which leveraged a recent development in our lab—the use of a light activated cross-linking node, 1,3,5,7-tetrakis-(p-benzylazide)-adamantane (TPBA)—to cross-link the PTAA layer and covalently bond it to the scaffold, ensuring that the hole-transport layer and adjacent metal electrode did not peel away from the scaffold-partitioned perovskite layer, a known weak layer as reported elsewhere.

Deposition of perovskite films by spin-coating onto substrates featuring the scaffolds resulted in the formation of arrays of hexagonal microcells which, when inspected by optical microscopy (FIG. 3B) and profilometry (FIGS. 3C-D), were shown to fill the scaffolds uniformly, exhibiting flat topography and consistent cell height (˜250 nm) between the scaffold walls. These observations addressed central questions for creating scaffold-reinforced CSCs of how effectively and uniformly the perovskite microcells could be formed, the variance of the height and topology of the individual hexagonal microcells, and the degree of conformal contact of each cell with the surrounding scaffold walls, and the resulting quality of perovskite crystals formed within the scaffold wells. Importantly, the microcell arrays formed consistently without the presence of unfilled microcells, thus preventing electrode-to-electrode contact and device shorting during subsequent fabrication steps.

Formation of the scaffold microcells did not show any dependence on the thickness of the intervening scaffold wall-width, or corresponding microcell surface area. Importantly, for the purpose of mechanical reinforcement, the perovskite formed within the scaffold and did not coat the scaffold sidewalls. The perovskite-free sidewalls ensured that a contiguous perovskite layer—a weak layer likely to be the source of delamination and device failure under applied stress—did not form and created a perovskite-free surface to which the PTAA-X capping layer adhered. By partitioning the fragile perovskite, the robust scaffolds can instead accommodate mechanical stresses, increasing the resistance to fracture.

B4) Mechanical experiments

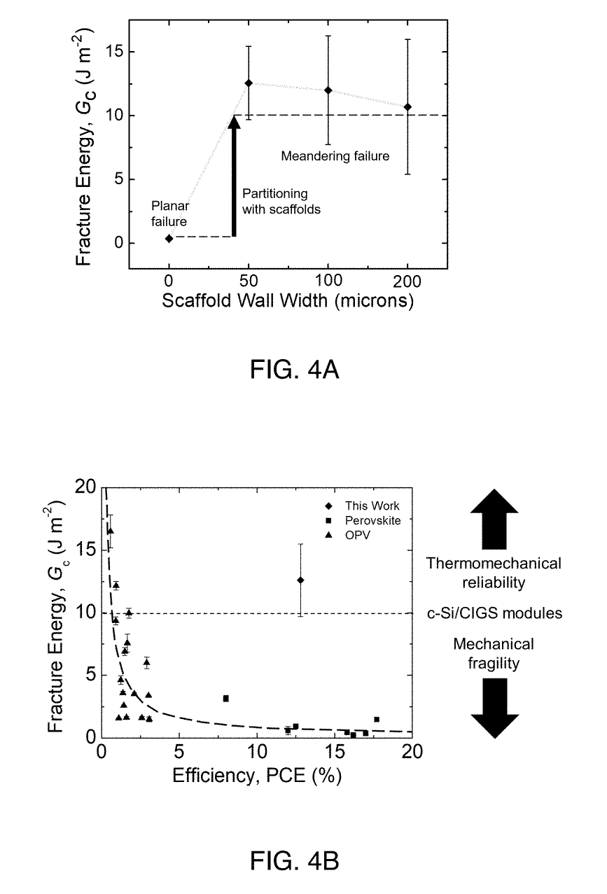

FIG. 4A shows fracture energy, or G_{c}, of planar and scaffold-partitioned CH₃NH₃PbI₃ perovskite layers. In planar specimens, the fracture path is directly through the brittle perovskite layer. Scaffold-partitioned cells exhibit a meandering fracture path—avoiding the scaffold—due to the disruption in the continuity of the brittle perovskite film. This meandering fracture path results in an increase of fracture energy more than 30 times greater than observed in planar perovskite. FIG. 4B shows the measured G_{c} versus PCE of solution-processed solar cells (i.e., OPV and perovskites) from reports in the literature compared to results from this work. A clear trade-off in reliability for efficiency is shown, except for the CSCs of this work, which demonstrate an order of magnitude or greater increase in fracture energy while maintaining high efficiency.

The impact of scaffold-partitioning on the mechanical stability of the perovskite layers was determined by fabricating double cantilever beam (DCB) specimens containing the CSCs and measuring their fracture energy, G_{c} (FIG. 4A). We previously reported that planar CH₃NH₃PbI₃ exhibited extreme mechanical fragility with a cohesive fracture energy of only 0.37±0.04 J m². The scaffold material, cross-linked SPR™ 3612 photoresist—a cresol novolac resin—was used to enhance the fracture resistance of the fragile CH₃NH₃PbI₃ layer. The architecture of these DCB specimens was Si/CH₃NH₃PbI₃ (planar and partitioned)/PTAA-X/Cr/Al/Epoxy/Si. All scaffold-partitioned perovskites exhibited a significant increase in fracture energy relative to planar perovskite. Interestingly, the scaffold layers exhibited similar fracture energies of 12.6±2.9, 12.0±4.3, and 10.7±5.3 J m⁻² for the 50, 100, and 200 μm wall widths, respectively. In comparison to planar and mesoporous perovskite films with varied compositions of A-site cations (Cs, formamidinium, methylammonium, butylammonium) and halides (I, Br, Cl) deposited from the solution-state by either spin or slot-die coating, the CSC fracture energy was 30-fold higher without sacrificing the photovoltaic performance of individual microcells (FIG. 4B). For reference, the fracture energies of conventional CIGS and c—Si cells are ˜10 J m⁻² and above, indicating that the CSC design positions perovskite solar cells in the domain of proven solar technologies that have demonstrated mechanical stability and service lifetimes.

The observed trend of decreasing fracture energy with increasing scaffold wall width can be rationalized in terms of two factors related to the scaffold wall thickness. Firstly, thicker walls present a larger surface area on top of the scaffold, which allows for the formation of a fragile and mechanically unshielded perovskite overburden, and secondly, thicker walls are coupled with smaller microcell perimeters, resulting in less surface area for the mechanically-enhancing cross-linking interaction between the scaffold and PTAA-X thus lowering overall resistance to fracture.

The fractured CSCs were analyzed by profilometry, and optical micrographs of the fractured interfaces were taken to highlight the fracture path. The predominant failure path did not follow the brittle perovskite and instead meandered throughout the entire test structure (FIG. 4A). This meandering fracture path, while passing through the fragile perovskite layer, required significant energy to fracture through the reinforcing scaffold containing the toughened PTAA-X and metal layers. While evidence of scaffold fracture was observed in a few regions, the scaffold remained largely intact upon the substrate on which it was originally deposited, indicating that the scaffold was resistant to cohesive failure and exhibited strong adhesion to the substrate.

We further probed the fracture interfaces using X-ray photoelectron spectroscopy (XPS) by performing survey scans of multiple regions of both the metal side and scaffold side of the fractured CSC specimens. Detection of Pb and I indicated that the fracture path was either through or against the perovskite. Detection of only C, N, and O indicated fracture through the encapsulating layers. XPS data agreed with the evidence provided by profilometry and optical microscopy that the fracture path meandered through the entire test structure, with some regions having failed cohesively through the perovskite and encapsulating layers and other regions having failed adhesively at the silicon substrate. Importantly, the number of regions in which detection of Pb and I occurred on the metal side of the CSC specimens increased with increasing scaffold wall width. This observation coincided with decreasing G_{c} and agreed with our hypothesis that thicker scaffold walls may allow for formation of more fragile perovskite overburden.

### B5) Photovoltaic Performance Experiments

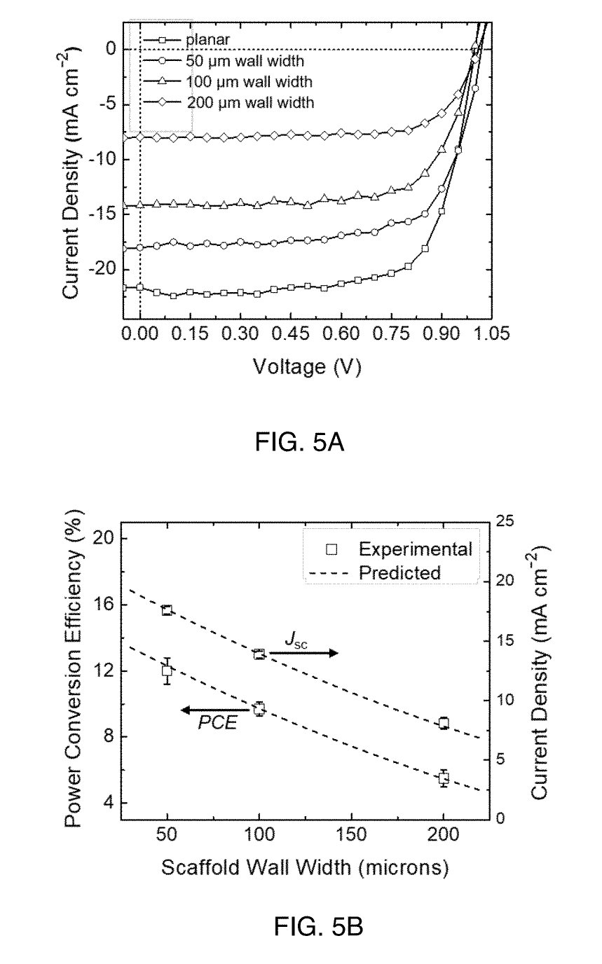

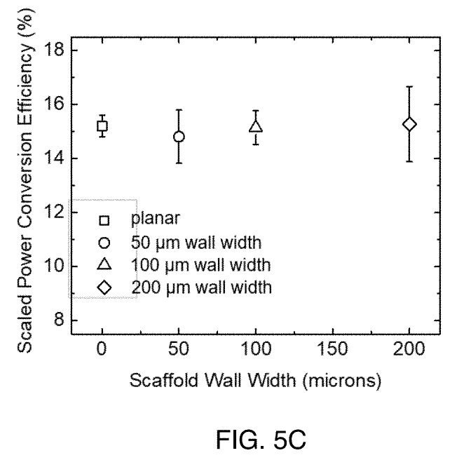

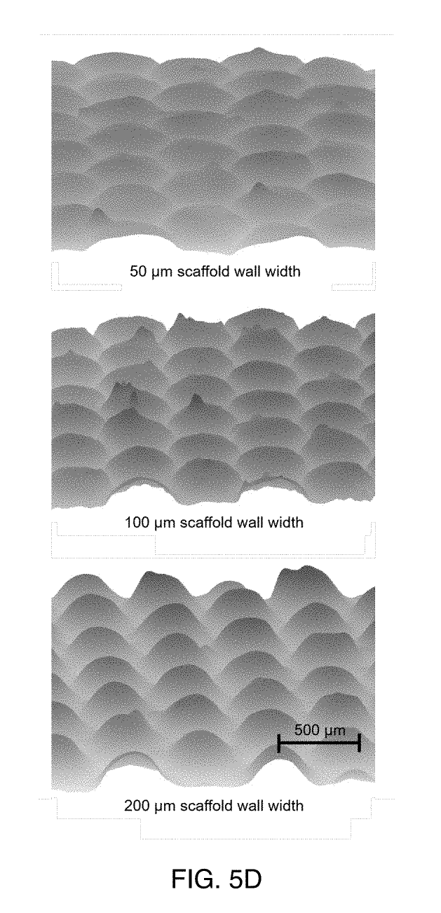

FIG. 5A shows J-V curves of representative devices with the architecture ITO/TiO₂ NPs/C₆₀/CH₃NH₃PbI₃/PTAA-X/Ag and scaffold wall widths of 50 μm, 100 μm, and 200 μm compared to a scaffold-free planar device. FIG. 5B shows the average PCE and J_{sc} of devices measured experimentally versus their PCE and J_{sc} predicted by multiplying the efficiency of the planar device by the corresponding microcell area fraction of the CSCs. FIG. 5C shows scaled-PCE of CSCs that were calculated by scaling the resulting CSC by the active area of the microcell array (i.e., dividing the experimental PCE by the microcell area fraction). The scaled-PCE is a measure of the PCE of the microcell array factoring out the inactive intervening scaffold layer, and indicates the device PCE that can possibly be achieved with efficient light management. FIG. 5D shows Laser Beam Induced Current maps of representative section of CSCs. Darker shading represents higher current and lighter shading, lower current. These scans demonstrate that the microcells are consistently defect-free.

While the improved mechanical stability of CSCs over planar devices was significant, the value of scaffold-partitioning would be limited if the improved stability coincided with a decrease in PCE. It was therefore important to determine the performance of CSCs compared to analogous planar devices and to extract the efficiency of the microcell arrays formed within the scaffold. Devices were fabricated with an architecture of ITO/TiO₂ NPs/C₆₀/CH₃NH₃PbI₃/PTAA-X/Ag. The J-V curves for the highest efficiency device is shown in FIG. 5A and the photovoltaic figures of merit are presented in Table 1. The average PCE of the planar devices was 15.2±0.4%, which are comparable to similar devices in the literature. Devices with a 50 μm scaffold wall width exhibited efficiencies of 12.0±0.8%, while devices with 100 μm and 200 μm scaffold wall widths had measured efficiencies of 9.7±0.4% and 5.5±0.4%, respectively. Notably, the CSC with the thinnest scaffold walls exhibited not only the highest fracture energy, but also the highest efficiency.

TABLE 1

| Solar Cell | V_{oc} | J_{sc} | FF | PCE | scaled-PCE |
|---|---|---|---|---|---|
| Type | (V) | (mA cm⁻²) | (%) | (%) | (%) |
| Planar | 1.00 ± 0.01 | 21.8 ± 0.5 | 70 ± 2 | 15.2 ± 0.4 | 15.2 |
| | | | | (15.8) | (15.8) |
| 50 μm wall | 1.00 ± 0.03 | 17.6 ± 0.3 | 69 ± 3 | 12.0 ± 0.8 | 14.8 |
| width | | | | (12.7) | (15.6) |
| 100 μm wall | 1.00 ± 0.02 | 13.9 ± 0.3 | 69 ± 1 | 9.7 ± 0.4 | 15.2 |
| width | | | | (10.4) | (16.3) |
| 200 μm wall | 0.99 ± 0.04 | 8.1 ± 0.5 | 70 ± 4 | 5.5 ± 0.5 | 15.3 |
| width | | | | (5.9) | (16.4) |

The figures of merit for the photovoltaic devices measured in this study, where
V_{oc} is the open-circuit voltage,
J_{sc} is the short-circuit current,
FF is the fill factor, and
PCE is the power conversion efficiency. The PCE of the best-performing devices are in parenthesis.
The scaled-PCE is calculated by dividing the PCE by the microcell area fraction.

Like PCE, a similar trend of decreasing short-circuit current, J_{sc}, with increasing wall width of the scaffolds was observed. The PCE and J_{sc} of the CSCs could be reliably predicted by a simple geometric argument based on the fraction of the surface area of the device occupied by the microcells (FIG. 1D). When these area fractions were multiplied by the measured J_{sc} and PCE for the planar devices, the values were nearly identical to those experimentally determined, demonstrating that there was no deleterious effects on individual microcell device quality when partitioned by a polymer scaffold (FIG. 5B).

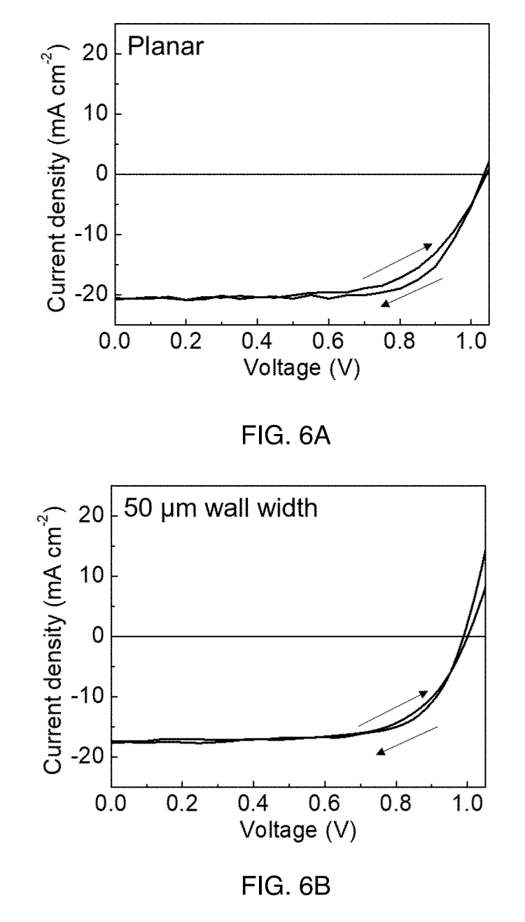

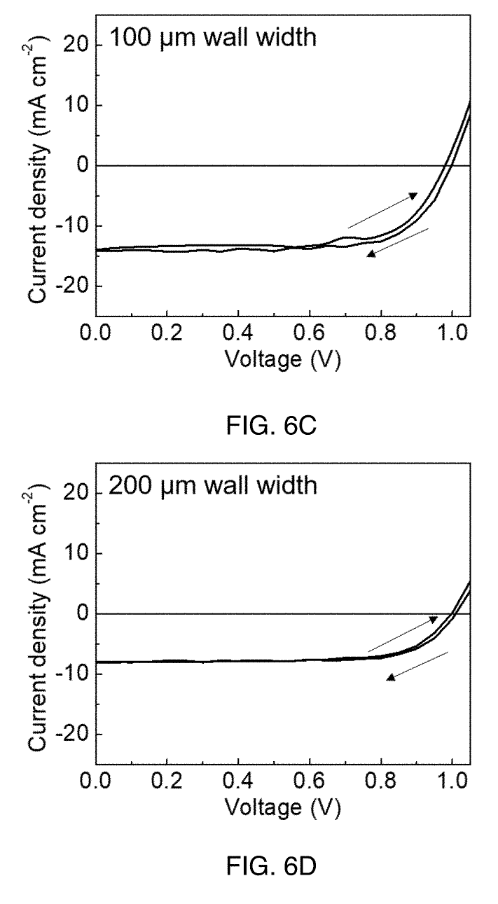

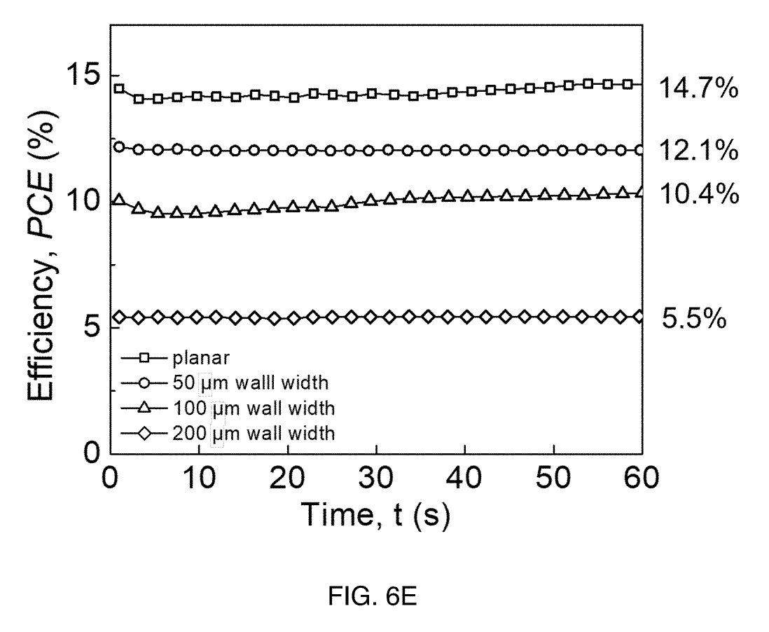

The presence of the scaffold did not affect device hysteresis (FIGS. 6A-D) or stabilized power output (FIG. 6E). Here FIG. 6A shows forward and backward scanned J-V curves of representative devices for a scaffold-free planar configuration. FIGS. 6B, 6C, 6D show similar curves for CSC configuration with scaffold wall width 50 μm, 100 μm, 200 μm, respectively. The observed minor hysteresis was attributed to the use of TiO₂ as the electron transport layer, and was minimized by depositing C₆₀ on top to modify the n-type contact and improve electron transfer. The TiO₂ was utilized instead of C₆₀ alone to achieve optimal PCE and minimize recombination at the ITO contact. Study of relative hysteresis of representative devices shows the PCE differs in magnitude of 9.1% for the scaffold-free, planar device and less than 5% for all CSC devices. FIG. 6E shows stabilized efficiency values from maximum power point tracking for scaffold-free planar and scaffold wall widths of 50 μm, 100 μm, and 200 μm.

External quantum efficiency (EQE) measurements were taken from representative devices to verify the same trends of short-circuit current occurred in the extracted J_{sc}. The experimental J_{sc} also closely followed the predicted values from multiplying the extracted short-circuit current by the area fraction. The extracted current from EQE closely matched that from the J-V curves for the same devices.

Unlike PCE and J_{sc}, the open-circuit voltage, V_{oc}, and fill-factor, FF, are not dependent on f_{MA}. V_{oc} was measured to be ˜1.0 V for all devices, indicating that the scaffolds did not substantially increase the amount of charge recombination occurring. Similarly, when compared to the planar devices, FF of the CSCs was not significantly different. The photovoltaic performance of CSCs and planar devices also performed similarly when exposed to environmental stressors. Encapsulated devices were exposed to ISOS D-3 conditions (85° C. and 85% relative humidity) for 6 weeks while maintaining over 60% of initial PCE, performing better than the encapsulated planar devices and indicating that packaged CSCs were resistant to thermal and environmental degradation. This result demonstrated that CSCs were not susceptible to any pathways for accelerated degradation or further chemical instability compared to planar devices and are compatible with long-term encapsulation strategies that will lead to greatly improved service lifetimes. Future work will involve more detailed studies to better understand the role of environmental stressors on long-term device reliability. The fundamental connection between material degradation and stressing parameters, together with their mechanistic origins, remains largely uncharacterized in perovskite solar cells. For example, the synergistic effect of UV photon energy and flux along with operational conditions of elevated heat and humidity have been shown to affect the kinetics of interface debonding in OPV devices.

The use of photon management strategies to focus incident solar radiation away from the scaffold and into the microcells (i.e., an array of lenses and concentrators or the addition of light-scattering particles directly into the scaffolds) would further increase the efficiency of the devices while maintaining the favorable mechanical stability afforded by the scaffold. As an illustration of the potential device CSC efficiencies, we assumed perfect photon management and calculated the scaled-PCEs of the microcells by dividing their batch-average efficiencies by their f and found that their scaled efficiencies were nearly identical to planar devices (FIG. 5C). This result alleviated any concern that scaffold partitioning would compromise device efficiency by introducing a high density of edge defects.

A potential criticism of this approach is that in the case of perfect photon management, light concentration is induced and the quantity of photons incident on the microcells is increased by a factor of 1 Sun/f_{MA}. To determine how the CSCs behaved under this increased light intensity, we simulated the concentration of light into each of the CSCs at light intensities of 100 mW cm² (simulating 1 Sun), 123 mW cm² (simulating 1 Sun concentrated into microcells with 50 μm scaffold wall widths), and 156 mW cm² (simulating 1 Sun concentrated into microcells with 100 μm scaffold wall widths) and observed that J_{sc} and PCE increased linearly with light intensity. This result shows that such concentrated light is not deleterious to the CSC performance, but crucially, that it results in a proportional increase in current, meaning that photon management could restore all of the efficiency loss observed from incorporating the scaffolds.

The photovoltaic responses of the CSCs were imaged using a laser-beam induced current (LBIC) system. The LBIC scans of the CSCs are shown in FIG. 5D. We observed that the current is roughly equivalent in each cell, again confirming the uniformity of fill and device formation within the scaffolds. The non-zero photovoltaic response of the scaffold regions and the curved profile observable in the CSC current maps are attributed to the resolution of the technique, which was limited by the laser spot diameter (˜35 μm).

In light of these results, it is reasonable to expect that with optimization of the scaffold and use of photon management strategies, the PCEs of CSCs can be increased to that of planar devices through the use of thinner scaffold walls and photon management. Another avenue of future interest would be fabrication of scaffolds using dense materials impermeable to methylamine, which has been shown to increase perovskite solar cell stability significantly. In doing so, the CSC design provides a strategy for solving challenges beyond mechanical fragility, including moisture sensitivity and chemical instability of this promising photovoltaic technology. The CSC design and uncompromised performance of the microcell array formed within the scaffold presents a much-needed pathway to overcoming hurdles facing the further development and commercialization of perovskite solar cell technology.

### B6) Conclusion

In summary, we have developed a device design capable of addressing the major issues associated with perovskite stability. We leveraged the remarkable flexibility of perovskite formation by showing that a vast array of microcells can be formed with high fidelity around preformed, patterned reinforcing scaffolds. We have demonstrated that integration of partitioning scaffolds into perovskite solar cells can be used to shield extrinsically the mechanically fragile perovskite absorber layer from mechanical stresses. The 30-fold increase in fracture resistance exhibited by the scaffold-reinforced CSCs repositions perovskite-based solar cell technology into the same domain of mechanical resilience of proven solar technologies like c—Si, CdTe and CIGS cells. We found that we could form microcells within the scaffold without impairing the performance of the perovskite material at all, and in some cases, created microcells with scaled efficiencies greater than those of planar cells. These results affirm the merit of design-for-reliability, which can be achieved in the development of device technologies without compromising efficiency.

1. An optoelectronic device structure comprising:
an electrically insulating matrix layer having laterally separated cells;
a plurality of optoelectronic device elements;
wherein each of the plurality of optoelectronic device elements occupies a corresponding one of the laterally separated cells of the electrically insulating matrix layer.

2. The optoelectronic device structure of claim 1, wherein all of the optoelectronic device elements are electrically connected to each other in parallel.

3. The optoelectronic device structure of claim 1, wherein the optoelectronic device elements include a perovskite material as an active medium that provides electrical charge carriers in response to incident illumination.

4. The optoelectronic device structure of claim 1, wherein the optoelectronic device elements partially fill the laterally separated cells in a vertical direction perpendicular to a lateral plane of the matrix layer.

5. The optoelectronic device structure of claim 1, wherein the matrix layer is impermeable to diffusion of chemical species of the optoelectronic device elements.

6. The optoelectronic device structure of claim 1, wherein the laterally separated cells are configured as a periodic array of cells.

7. The optoelectronic device structure of claim 6, wherein the laterally separated cells are configured as an array of regular hexagonal cells.

8. The optoelectronic device structure of claim 1, wherein the laterally separated cells are configured as an aperiodic arrangement of cells.

9. The optoelectronic device structure of claim 1, wherein the optoelectronic device structure is configured as a device selected from the group consisting of: solar cells, photovoltaic devices, light emitting diodes, and photodetectors.

10. The optoelectronic device structure of claim 1, further comprising a substrate on which the matrix layer is disposed, wherein the substrate is flexible or rigid.
